(19) United States
(12) Patent Application Publication
(10) Pub. No.: US 2026/0052940 A1
(43) Pub. Date: Feb. 19, 2026

(54) SHUTTLE AND CHIP TRANSFER APPARATUS INCLUDING THE SAME

(71) Applicant: Samsung Electronics Co., Ltd., Suwon-si (KR)

(72) Inventors: Jonggill LEE, Suwon-si (KR); Junho CHO, Suwon-si (KR)

(73) Assignee: Samsung Electronics Co., Ltd., Suwon-si (KR)

(21) Appl. No.: 19/062,152

(22) Filed: Feb. 25, 2025

(30) Foreign Application Priority Data
Aug. 19, 2024 (KR) 10-2024-0110744

(51) Int. Cl. H01L 21/677

(52) U.S. Cl. CPC H01L 21/67706; H01L 21/67718

(57) ABSTRACT

A shuttle including: at least one collet configured to support at least one semiconductor chip, a stage configured to detachably support the at least one collet, and a rotational driving mechanism configured to rotate the stage in a first direction, the first direction being an axial direction, the at least one collet including, a support body configured to support the at least one semiconductor chip, and a ferromagnetic body on one side of the support body, and the stage including, a stage body including at least one detachment surface from which the at least one collet detaches, the detachment surface facing in a direction perpendicular to the first direction, and at least one electromagnet on the stage body, the at least one electromagnet configured to attach to or detach from the ferromagnetic body.

### CROSS-REFERENCE TO RELATED APPLICATION

This U.S. non-provisional application claims the benefit of priority under 35 U.S.C. § 119 to Korean Patent Application No. 10-2024-0110744, filed on Aug. 19, 2024, in the Korean Intellectual Property Office, the disclosure of which is incorporated by reference herein in its entirety.

### BACKGROUND

One or more example embodiments of the inventive concepts relate to a shuttle for transferring semiconductor chips, a chip transfer apparatus including the same, a chip transfer system including the same, and/or a method of operating a chip transfer apparatus, etc., and more particularly to a shuttle capable of automatically replacing a collet, a chip transfer apparatus that includes such a shuttle, a chip transfer system including the shuttle, and/or a method of operating the chip transfer apparatus including the shuttle, etc.

Generally, a semiconductor chip is transferred between each process by a shuttle. The semiconductor chip is placed on each of a plurality of collets arranged on a stage of the shuttle. Since the collets have limited durability, they must be replaced on the stage at regular intervals. Until recently, such collet replacement has been performed manually after stopping the chip transfer and processing equipment. Due to such manual replacement, there is a problem that a lot of time is consumed in replacing the collet.

### SUMMARY

One or more example embodiments of the inventive concepts provide a shuttle that automatically replaces a collet, a chip transfer apparatus including the same, a chip transfer system including the same, and/or a method of operating a chip transfer apparatus, etc.

Some example embodiments of the inventive concepts provide a shuttle which shortens the collet replacement time, a chip transfer apparatus including the same, a chip transfer system including the same, and/or a method of operating a chip transfer apparatus, etc.

According to at least one example embodiment, there is provided a shuttle including: at least one collet configured to support at least one semiconductor chip, a stage configured to detachably support the at least one collet, and a rotational driving mechanism configured to rotate the stage in a first direction, the first direction being an axial direction, the at least one collet including, a support body configured to support the at least one semiconductor chip, and a ferromagnetic body on one side of the support body, and the stage including, a stage body including at least one detachment surface from which the at least one collet detaches, the detachment surface facing in a direction perpendicular to the first direction, and at least one electromagnet on the stage body, the at least one electromagnet configured to attach to or detach from the ferromagnetic body.

According to at least one example embodiment, there is provided a chip transfer apparatus, including: a shuttle including at least one collet, the at least one collet configured to support at least one semiconductor chip, a stage configured to detachably support the at least one collet, and a rotational driving mechanism configured to rotate the stage in a first direction, the first direction being an axial direction, and a standby apparatus configured to store the at least one collet prior to the at least one collet being attached to the stage, the collet including, a support body configured to support the at least one semiconductor chip, and a ferromagnetic body installed on one side of the support body, and the stage including, a stage body including at least one detachment surface from which the at least one collet detaches, the detachment surface facing a direction perpendicular to the first direction, and at least one electromagnet on the stage body, the at least one electromagnet configured to attach to and detach from the ferromagnetic body.

According to at least one example embodiment, there is provided a chip transfer apparatus, including: a shuttle configured to store at least one collet, the collet configured to support at least one semiconductor chip, a stage configured to detachably support the at least one collet a rotational driving mechanism configured to rotate the stage in a first direction, the first direction being an axial direction, and a collection container configured to collect the at least one collet removed from the stage, the collet including, a support body configured to support the at least one semiconductor chip, and a ferromagnetic body on one side of the support body, the stage including, a stage body including at least one detachment surface from which the at least one collet detaches, the detachment surface facing in a direction perpendicular to the first direction, and at least one electromagnet on the stage body, the at least one electromagnet configured to attach to or detach from the ferromagnetic body.

### BRIEF DESCRIPTION OF DRAWINGS

The above and other features of one or more example embodiments of the inventive concepts will be more clearly understood from the following detailed description, taken in conjunction with the accompanying drawings.

FIG. 1 is a perspective view schematically illustrating a chip transfer apparatus according to at least one example embodiment of the inventive concepts.

FIG. 2 is a partially exploded perspective view illustrating a part of the shuttle illustrated in FIG. 1 according to some example embodiments.

FIG. 3 and FIG. 4 are views sequentially illustrating an example of a method for the chip transfer apparatus of FIG. 1 to replace collets along the first direction according to some example embodiments.

FIG. 5 is a partial perspective view illustrating a part of the stage according to at least one example embodiment.

FIG. 6 is a vertical cross-sectional view illustrating a cross-section of the stage of FIG. 5 cut along a direction perpendicular to the first direction according to some example embodiments.

FIG. 7 is a partial perspective view illustrating a part of a stage according to at least one example embodiment.

FIG. 8 is a partial perspective view illustrating a part of a stage according to at least one example embodiment.

FIG. 9 is a view illustrating a stage body according to at least one example embodiment along a first direction.

FIG. 10 is a view illustrating a stage body according to at least one example embodiment along a first direction.

FIGS. 11 to 13 are views sequentially illustrating an example of a method for the chip transfer apparatus provided with the stage body of FIG. 9 to replace collets along the first direction according to some example embodiments.

### DETAILED DESCRIPTION

Hereinafter, some example embodiments of the inventive concepts will be described in detail and with sufficient clarity for those of ordinary skill in the art to easily implement the inventive concepts.

A chip transfer apparatus of at least one example embodiment of the inventive concepts may be used to move a semiconductor chip (hereinafter referred to as a “chip”) in a semiconductor manufacturing process between locations where each process is performed. For example, the chip transfer apparatus of at least one example embodiment of the inventive concepts may transfer a chip on which a dicing process has been completed to a location where a bonding process is performed, but the example embodiments are not limited thereto.

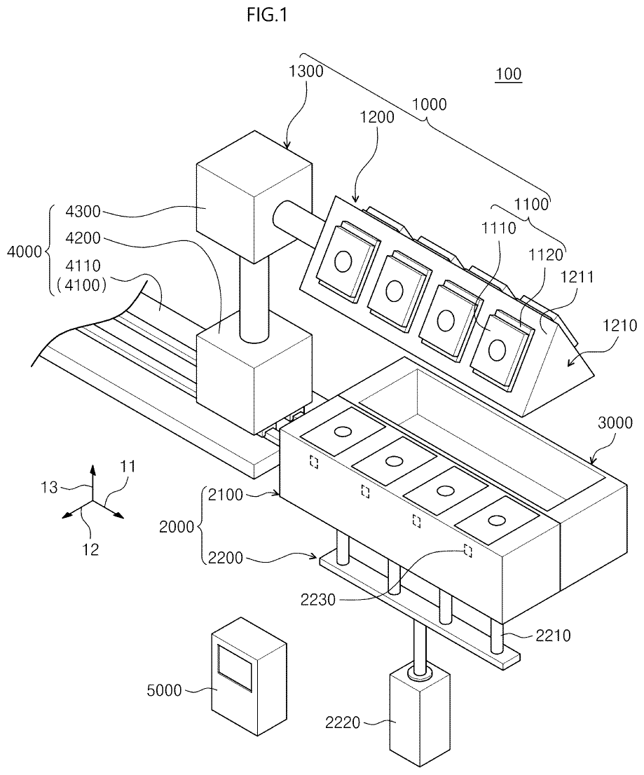

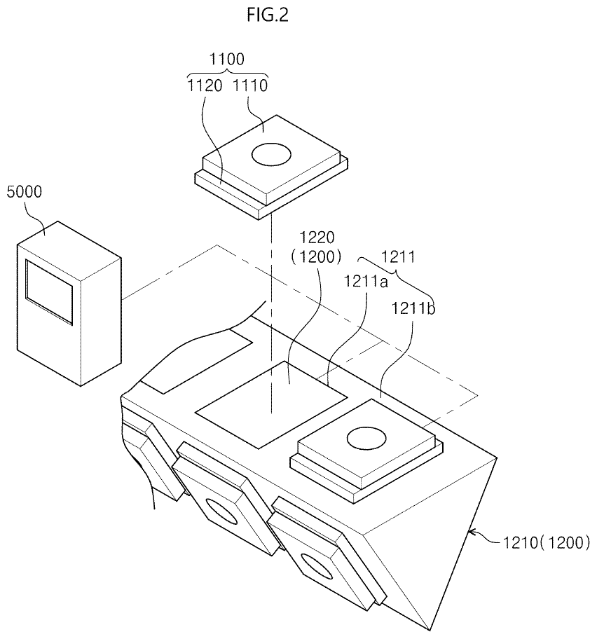

FIG. 1 is a perspective view schematically illustrating a chip transfer apparatus 100 according to at least one example embodiment of the inventive concepts. FIG. 2 is a partially exploded perspective view illustrating a part of the shuttle 1000 illustrated in FIG. 1.

Referring to FIGS. 1 and 2, the chip transfer apparatus 100 may include a shuttle 1000, a standby portion 2000 (e.g., a standby apparatus, etc.), a collection container 3000, a shuttle moving portion 4000 (e.g., a shuttle mover, a shuttle moving device, etc.), and/or a controller 5000, etc., but is not limited thereto.

The shuttle 1000 accommodates and moves. The shuttle 1000 may accommodate a plurality of semiconductor chips, but is not limited thereto. According to some example embodiments, the shuttle 1000 may include at least one collet 1100, at least one stage 1200, and/or at least one rotational driving portion 1300, etc., but is not limited thereto.

Hereinafter, in at least one example embodiment, the direction of a rotation axis along which the stage 1200 is rotated by the rotational driving portion 1300 (e.g., rotational driving mechanism, etc.) is referred to as the first direction 11, and when viewed from above, the direction perpendicular to the first direction 11 is referred to as the second direction 12, and the direction perpendicular to the first direction 11 and the second direction 12 is referred to as the third direction 13.

The collet 1100 supports the chip. One chip may be supported by one collet 1100, but the example embodiments are not limited thereto. According to some example embodiments, the collet 1100 may include at least one support body 1110 and/or at least one ferromagnetic body 1120, etc., but is not limited thereto.

The support body 1110 supports and/or directly supports the chip. The support body 1110 may be provided as a plate structure, but is not limited thereto. The support body 1110 may be provided with a material having elasticity and/or flexibility and thus the chip is not damaged when supported. For example, the support body 1110 may be provided with a rubber material, but is not limited thereto.

The ferromagnetic body 1120 is installed on one side of the support body 1110. Therefore, the chip may be supported on the other side of the support body 1110. The ferromagnetic body 1120 may be provided as a plate structure having a size and shape corresponding to the support body 1110, but the example embodiments are not limited thereto. Additionally, or alternatively, the ferromagnetic body 1120 may be provided with various appropriate sizes and/or structures such that it may be attached to an electromagnet 1220 by the magnetic force of the electromagnet 1220.

The stage 1200 detachably supports the collet 1100. The stage 1200 may support a plurality of collets 1100. According to some example embodiments, the stage 1200 may include at least one stage body 1210 and/or at least one electromagnet 1220, etc., but is not limited thereto.

The stage body 1210 includes at least one detachment surface 1211 from which the collet 1100 is attached and/or detached. The detachment surface 1211 may be a surface facing a direction perpendicular to the first direction 11 of the stage body 1210, but is not limited thereto. According to some example embodiments, the stage body 1210 may be provided in a polygonal columnar shape having a longitudinal direction parallel to the first direction 11, but is not limited thereto. In addition, at least some of the side surfaces of the stage body 1210 may be provided as detachment surfaces 1211. For example, the stage body 1210 may be provided in a regular triangular columnar structure having a longitudinal direction parallel to the first direction 11, but the example embodiments are not limited thereto, and the stage body 1210 may have other shapes. In addition, the entire side surfaces of the stage body 1210 may be provided as detachment surfaces 1211. On each of the detachment surfaces 1211, a plurality of collets 1100 may be arranged at desired and/or regular intervals along the first direction 11. In this way, since the stage body 1210 is provided with a polygonal column structure, the stage body 1210 may accommodate a large number of chips compared to stage bodies provided with a conventional plate structure.

Hereinafter, a description will be given based on a case where the entire side surfaces of the stage body 1210 are provided as detachment surfaces 1211, but the example embodiments are not limited thereto.

The electromagnet 1220 detaches the ferromagnetic body 1120. The electromagnet 1220 is installed in the stage body 1210. According to some example embodiments, the electromagnet 1220 may be provided in an area of the detachment surface 1211 corresponding to the ferromagnetic body 1120 of the collet 1100 attached to the detachment surface 1211. The electromagnet 1220 may be partially or completely embedded in the stage body 1210, but is not limited thereto, and for example may be arranged on top of a surface of the stage body 1210.

The rotational driving portion 1300 rotates the stage 1200 with the first direction 11 as the axial direction. The rotational driving portion 1300 may be connected to one end of the stage body 1210 and may rotate the stage body 1210 with the first direction 11 as the axial direction. The rotational driving portion 1300 may rotate the stage body 1210 by an interval by which each of the detachable surfaces 1211 of the stage body 1210 sequentially faces a desired and/or certain direction. When the stage body 1210 is provided in a regular polygonal columnar structure, the rotational driving portion 1300 may rotate the stage body 1210 by a desired and/or certain angle unit at which each of the detachable surfaces 1211 sequentially faces downward, e.g., a surface of the stage body 1210 is parallel to a surface of the standby portion 2000, etc. According to some example embodiments, when the stage body 1210 is provided in a regular triangular columnar structure, the rotational driving portion 1300 may rotate the stage body 1210 every 60-degrees, but the example embodiments are not limited thereto. The rotational driving portion 1300 may have various structures and configurations for rotating the stage body 1210 at regular intervals as described above. For example, the rotational driving portion 1300 may include a step motor, etc., but is not limited thereto.

The collets wait to be attached to the stage 1200 in the standby portion 2000. One or more collets 1100 may wait in the standby portion 2000.

The collection container 3000 collects the collets 1100 that fall off, are removed from, and/or are detached from the stage 1200. According to some example embodiments, the collection container 3000 includes and/or defines a space inside (e.g., a cavity, etc.) that accommodates and/or receives collets 1100 that fall off from the detachment surface 1211, etc. The collection container 3000 has an open upper surface, but is not limited thereto.

The shuttle moving portion 4000 may move the shuttle 1000. According to some example embodiments, the shuttle moving portion 4000 may include a horizontal moving portion 4100 (e.g., horizontal moving mechanism, etc.), a height adjusting portion 4200 (e.g., height adjuster, height adjusting mechanism, etc.), and/or a horizontal rotating portion 4300 (e.g., horizontal rotator, horizontal rotating mechanism, etc.), but is not limited thereto. The horizontal moving portion 4100, the height adjusting portion 4200, and/or the horizontal rotating portion 4300 illustrated in FIG. 1 are examples, and the positions and/or shapes of the horizontal moving portion 4100, the height adjusting portion 4200, and/or the horizontal rotating portion 4300 are not limited thereto.

The horizontal moving portion 4100 moves the shuttle 1000 along a horizontal direction. The horizontal moving portion 4100 may be provided using various structures and/or configurations that may move the shuttle 1000 in a horizontal direction. According to some example embodiments, the horizontal moving portion 4100 may include a rail 4110 and a horizontal driver (not illustrated), but is not limited thereto.

The rail 4110 may be installed on the floor along the moving path of the shuttle 1000, but is not limited thereto. The horizontal moving portion 4100 may move the shuttle 1000 along the rail 4110. In addition, the horizontal moving portion 4100 may move the shuttle 1000 in a direction perpendicular to the direction of the rail 4110, but is not limited thereto.

The horizontal driver provides a driving force by which the horizontal moving portion 4100 may move the shuttle 1000 in a horizontal direction. The horizontal driver may include an electric motor, but is not limited thereto.

The height adjusting portion 4200 adjusts the height of the shuttle 1000, e.g., the height adjusting portion 4200 may move the shuttle 1000 in a vertical direction, etc. The height adjusting portion 4200 may be provided using various structures and/or configurations that may adjust the height of the shuttle 1000. According to some example embodiments, the height adjusting portion 4200 may include an electric motor that provides a driving force to move the shuttle 1000 in an up-and-down direction, but is not limited thereto.

The horizontal rotating portion 4300 rotates the shuttle 1000 in a direction parallel to the third direction 13 as a rotation axis, but is not limited thereto. The horizontal rotating portion 4300 may be provided using various structures and/or configurations that may rotate the shuttle 1000 in the direction parallel to the third direction 13 as a rotation axis, etc. According to some example embodiments, the horizontal rotating portion 4300 may rotate the shuttle 1000 about a position adjacent to one end of the stage 1200. The horizontal rotating portion 4300 may include an electric motor that provides a driving force that may rotate the shuttle 1000, etc.

The controller 5000 (e.g., processing circuitry, etc.) controls each component of the chip transfer apparatus 100. According to some example embodiments, the controller 5000 may turn the electromagnet 1220 on/off. The controller 5000 may control the movement of the movable components, e.g., the horizontal moving portion 4100, the height adjusting portion 4200, and/or the horizontal rotating portion 4300, etc., of the chip transfer apparatus 100. For example, the controller 5000 may measure, sense, and/or obtain the positions of each of the movable components of the chip transfer apparatus 100, and based on the measured, sensed, and/or obtained positions and other settings and/or input data, may move the movable components of the chip transfer apparatus 100 in a desired direction as much as desired, and may turn the electromagnet 1220 on/off, etc., but the example embodiments are not limited thereto. According to some example embodiments, the controller 5000 may be implemented as processing circuitry. The processing circuitry may include hardware or hardware circuit including logic circuits; a hardware/software combination such as a processor executing software and/or firmware; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc., but is not limited thereto.

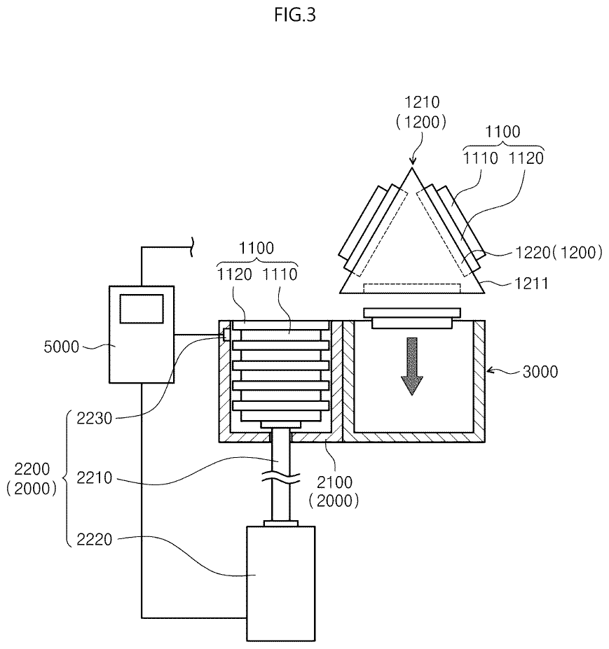

FIG. 3 and FIG. 4 are views sequentially illustrating an example of a method for the chip transfer apparatus of FIG. 1 to replace collets along the first direction.

Referring to FIGS. 1, 3, and 4, the standby portion 2000 may include a standby container 2100 and/or a collet lifting portion 2200, etc., but the example embodiments are not limited thereto.

The standby container 2100 includes and/or defines at least one space (e.g., cavity, etc.) in which a collet 1100 is accommodated and/or received. A plurality of collets 1100 may be accommodated and/or received in a stacked manner inside a single standby container 2100. The standby container 2100 may have an open upper surface, but is not limited thereto. The spaces of the standby container 2100 may be provided in a number corresponding to the number of collets 1100 that may be arranged on one detachable surface 1211, but is not limited thereto. The spaces of the standby container 2100 may be arranged to be spaced apart from each other at intervals corresponding to the intervals between the collets 1100 that may be arranged on one detachable surface 1211 along the first direction 11. Each of the spaces of the standby container 2100 may be provided in a size and/or shape corresponding to the collets 1100 when viewed from above for the collets 1100 to be maintained in a stacked state inside, but is not limited thereto. Each of the collets 1100 in the standby container 2100 may be positioned for the ferromagnetic body 1120 faces upward to be attached to the electromagnet 1220 positioned above the collets.

The collet lifting portion 2200 raises the collets 1100 accommodated in each of the spaces of the standby container 2100 to a position where the collets may be attached to the detachment surface 1211 by the magnetic force of the respective electromagnet 1220. For example, when the highest one of the collets 1100 accommodated in the space of the standby container 2100 is discharged and/or removed from the standby container 2100, the collet lifting portion 2200 raises the remaining collets 1100 in the space of the standby container 2100 by a height unit corresponding to the height of one collet 1100. According to some example embodiments, the collet lifting portion 2200 may include a lift shaft 2210, a step driver 2220, and/or a collet detection sensor 2230, etc., but is not limited thereto.

The lift shaft 2210 may support collets 1100 accommodated and/or stored in the standby container 2100. The lift shaft 2210 may be provided to be movable in the up-and-down direction, but is not limited thereto. According to some example embodiments, the lift shaft 2210 may extend from inside the standby container 2100 to outside of (e.g., above, etc.) the standby container 2100 by penetrating the bottom surface of the standby container 2100. The upper end of the lift shaft 2210 may support the bottom surface of one of the collets 1100 accommodated in and/or stored in the standby container 2100 located at the lowest position, but is not limited thereto.

The step driver 2220 may generate a driving force to raise and/or lower the lift shaft 2210 by the height unit (e.g., a desired height and/or desired distance, etc.). The step driver 2220 may include a step motor, but is not limited thereto.

The collet detection sensor 2230 may detect whether the collet 1100 located at the top position of the collets 1100 in the standby container 2100 is taken out and/or removed from the standby container 2100, etc. The collet detection sensor 2230 transmits the detection result to the controller 5000. The collet detection sensor 2230 may be provided correspondingly for each space and/or cavity of the standby container 2100 where the collet 1100 is accommodated and/or stored, etc.

The space of the collection container 3000 where the collet 1100 is collected may be larger than the space of the standby container 2100 having the open upper surface when viewed from above, and therefore the collet 1100 falling from the stage body 1210 may be stably collected, but the example embodiments are not limited thereto. According to some example embodiments, the space of the collection container 3000 having the open upper surface where the collet 1100 is collected may be provided as a single space (e.g., cavity, etc.) having a size in which all the collets 1100 attached to one detachment surface 1211 may be stably introduced even when all the collet 1100 is dropped simultaneously attached to one detachment surface 1211, but the example embodiments are not limited thereto. The standby container 2100 and the collection container 3000 may be arranged along the second direction 12 with respect to each other.

Hereinafter, an example of a method in which the chip transfer apparatus 100 of FIG. 1 replaces the collet 1100 on the stage 1200 will be described, but the example embodiments are not limited thereto.

In one or more of the methods described below, the operation of each configuration is performed by the above-described rotational driving portion 1300, the collet lifting portion 2200, and/or the shuttle moving portion 4000, etc., and may be controlled by the controller 5000, but the example embodiments are not limited thereto.

Referring to FIG. 3, in order to separate the collet 1100 to be separated from the stage body 1210, the electromagnet 1220 corresponding to the collet 1100 to be separated is turned off while the stage body 1210 is positioned at a separation position. The separation position is a position where the stage body 1210 is positioned above the collection container 3000 to which the collet 1100 that has fallen from the detachment surface 1211 falls to the open upper surface of the collection container 3000.

According to some example embodiments, the separation position may be a position where the stage body 1210 is positioned above the collection container 3000, making the detachment surface to which the collet 1100 to be separated is attached face the open upper surface of the collection container 3000 to detach the collet 1100 to be separated from the stage body 1210.

As described above, when the electromagnet 1220 corresponding to the collet 1100 to be separated is turned off while the stage body 1210 is positioned at the separation position, the collet 1100 to be separated is separated from the detachment surface 1211 and collected by the collection container 3000.

Referring to FIG. 4, the electromagnet 1220 corresponding to the collet 1100 to be attached is turned on when the stage body 1210 is positioned at the attachment position, thereby attaching the collet 1100 to be attached to the stage body 1210. The attachment position is a position where the stage body 1210 is positioned above the standby container 2100, making one of the detachment surfaces 1211 face the open upper surface of the standby container 2100. According to some example embodiments, one of the detachment surfaces 1211 for attaching the collet 1100 may face the upper surface of the standby container 2100, when the stage body 1210 is positioned at the attachment position. The stage body 1210 may be positioned at a height sufficiently close to the upper surface of the standby container 2100 at the attachment position in order to enable the electromagnet 1220 to electromagnetically attract the desired collet 1100 from the standby container 2100, or in other words, making the top one of the collets 1100 waiting in the standby container 2100 be attached thereto when the electromagnet 1220 installed on the detachment surface 1211 for attaching the collet 1100 is turned on.

As described above, the top one of the collets 1100 waiting in the standby container 2100 is detached from the standby container 2100 and attaches to the detachment surface 1211 when the electromagnet 1220 corresponding to the collet 1100 to be attached is turned on while the stage body 1210 is positioned at the attachment position. After this, the collet lifting portion 2200 raises the remaining collets 1100 remaining in the standby container 2100 by the thickness (e.g., height, etc.) of the collet 1100, positioning the top one of the remaining collets 1100 to be attached to the detachment surface 1211 by the electromagnet 1220, etc.

According to some example embodiments, the attachment process of the collet 1100 of FIG. 4 may be performed on the detachment surface 1211 on which the detachment process of the collet 1100 of FIG. 3 is performed, but is not limited thereto. Accordingly, the replacement process of the collet 1100 for the stage body 1210 may be performed by moving the stage body 1210 from the separation position above the collection container 3000 to the attachment position above the standby container 2100, etc.

Therefore, when the replacement of the collet 1100 is performed for the multiple detachment surfaces 1211 of the stage body 1210, after the processes of FIGS. 3 and 4 are sequentially performed for one detachment surface 1211, the stage body 1210 is rotated about an axis in a direction parallel to the first direction 11 and moves above the upper surface of the collection container 3000 to make another detachment surface 1211 face the upper surface of the collection container 3000, etc.

To reduce the chances of and/or prevent a collision between the stage body 1210 and the standby container 2100 and/or the collet 1100 in standby during the rotation, the stage body 1210 may be raised to a height at which the collision is reduced and/or prevented before the rotation, and then lowered to a separation position after the rotation, but the example embodiments are not limited thereto. After this, the processes of FIGS. 3 and 4 described above may be sequentially performed for another detachment surface 1211, etc.

Such a replacement operation of the collet 1100 may be performed for some or all of the collets 1100 attached to each of the detachment surfaces 1211.

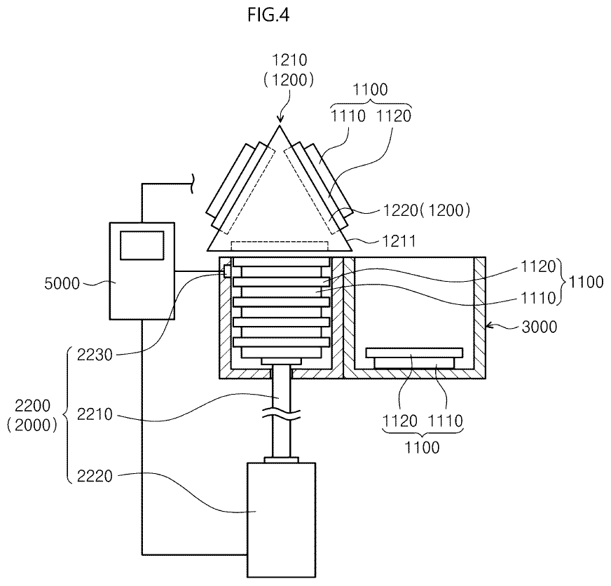

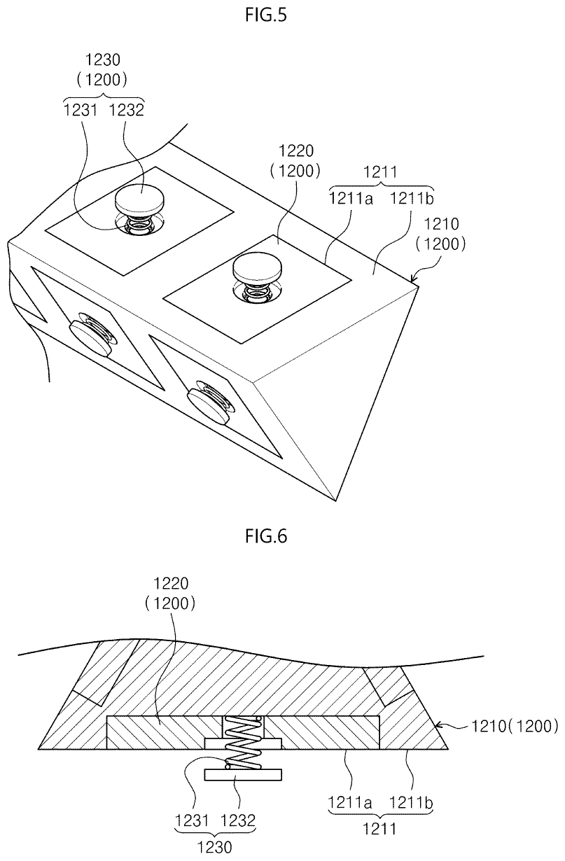

FIG. 5 is a partial perspective view illustrating a part of the stage 1200 according to at least one example embodiment. FIG. 6 is a vertical cross-sectional view illustrating a cross-section of the stage 1200 of FIG. 5 cut along a direction perpendicular to the first direction 11.

Referring to FIGS. 5 and 6, the stage 1200 may further include a separation auxiliary portion 1230 (e.g., separation auxiliary mechanism, etc.). The separation auxiliary portion 1230 applies a force to the collet 1100 attached to the detachment surface 1211 in a direction away from the detachment surface 1211. The force is smaller than the magnetic force acting between the ferromagnetic body 1120 of the collet 1100 attached to the detachment surface 1211 and the electromagnet 1220 when the electromagnet 1220 is turned on, and larger than the residual magnetic force acting between the ferromagnetic body 1120 and the electromagnet 1220 when the electromagnet 1220 is turned off. According to some example embodiments, the separation auxiliary portion 1230 may include an elastic body 1231 and/or a contact portion 1232, etc., but is not limited thereto.

The clastic body 1231 may be installed on the detachment surface 1211 and may apply an elastic force to the collet 1100 attached to the detachment surface 1211 in a direction away from the detachment surface 1211. The elastic body 1231 may be provided in a coil spring structure, but is not limited thereto.

The contact portion 1232 (e.g., contact area, contact region, etc.) may be located at one end far from the detachment surface 1211 of the clastic body 1231 and may contact the collet 1100 attached to the detachment surface 1211. The contact portion 1232 may be provided with at least one material that does not stick to a magnet. The contact portion 1232 may increase the contact area with the collet 1100 to decrease and/or prevent the elastic body 1231 and the collet 1100 from being worn due to contact with each other. In addition, since the contact portion 1232 is provided with at least one material that does not stick to a magnet, the influence of the residual magnetic force on the ferromagnetic body 1120 when the electromagnet 1220 is turned off may be reduced.

At least one insertion hole may be formed in the detachment surface 1211 into which the elastic body 1231 and the contact portion 1232 may be inserted and may not protrude outwardly from the detachment surface 1211 when the collet 1100 is attached to the detachment surface 1211, allowing the collet 1100 to be stably and/or more stably attached to the detachment surface 1211.

As described above, since the separation auxiliary portion 1230 is provided, the collet 1100 to be detached from the stage body 1210 may be decreased and/or prevented from remaining in contact to the detachment surface 1211 due to the residual magnetic force of the electromagnet 1220 that is turned off.

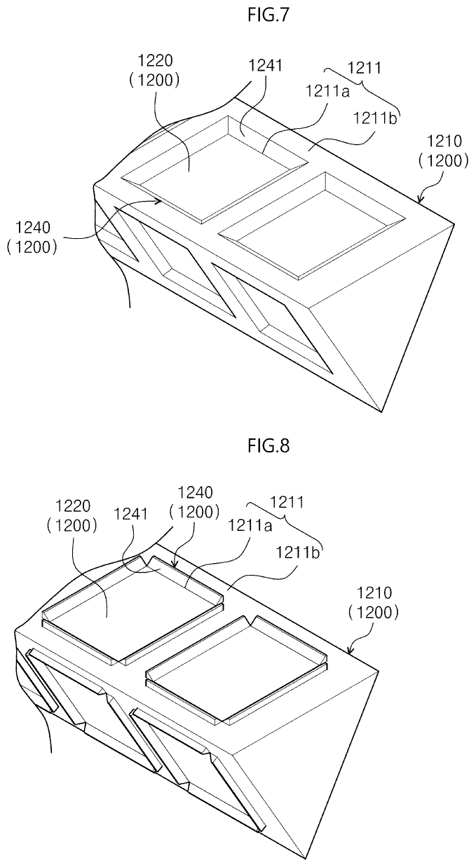

FIG. 7 is a partial perspective view illustrating a part of a stage 1200 according to at least one example embodiment.

Referring to FIG. 7, the stage 1200 may further include a guide portion 1240 (e.g., guides, guide surfaces, etc.), but is not limited thereto. The guide portion 1240 guides and/or directs the collet 1100 being attached to the stage body 1210 to a correct position on the detachment surface 1211. According to some example embodiments, the guide portion 1240 may include a guide slope 1241, but is not limited thereto. The guide slope 1241 surrounds the attachment area 1211a. And the guide slope 1241 is inclined toward the inside of the stage body 1210 and the attachment area 1211a. The attachment area 1211a is the area of the detachment surface 1211 where the collet 1100 is attached.

According to some example embodiments, the attachment area 1211a may be recessed further into the inside of the stage body 1210 than the surrounding area 1211b of the detachment surface 1211 excluding the attachment area 1211a, but is not limited thereto. And the guide slope 1241 may be formed between the attachment area 1211a and the surrounding area 1211b, but is not limited thereto.

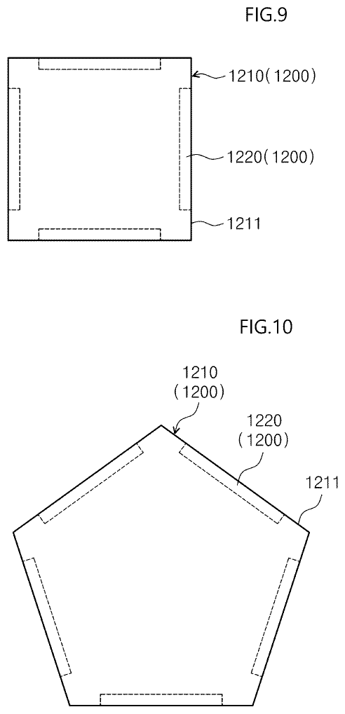

FIG. 8 is a partial perspective view illustrating a part of a stage 1200 according to at least one example embodiment.

Referring to FIG. 8, unlike the guide portion 1240 of FIG. 7, the guide portion 1240 may protrude outwardly from the stage body 1210 more than the detachment surface 1211. In this case, the surface of the guide portion 1240 facing the attachment area 1211a may be provided as the guide slope 1241.

The collet 1100 attached to the stage body 1210 may be guided to the attachment area 1211a along the guide slope 1241.

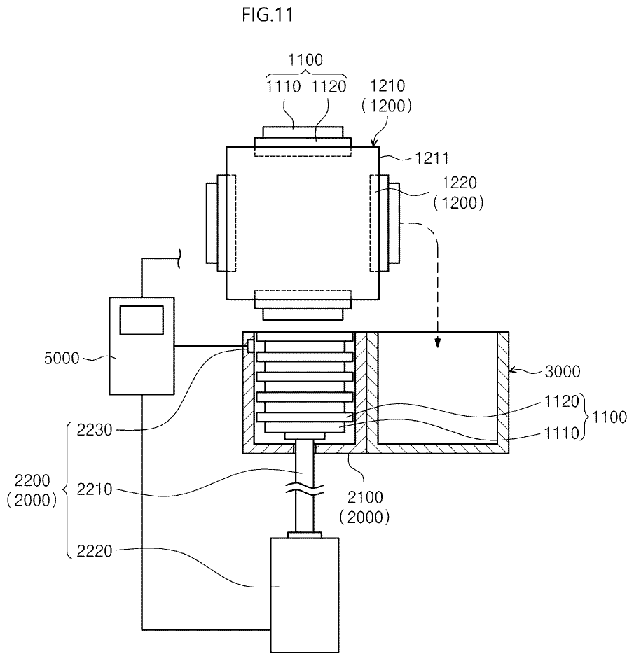

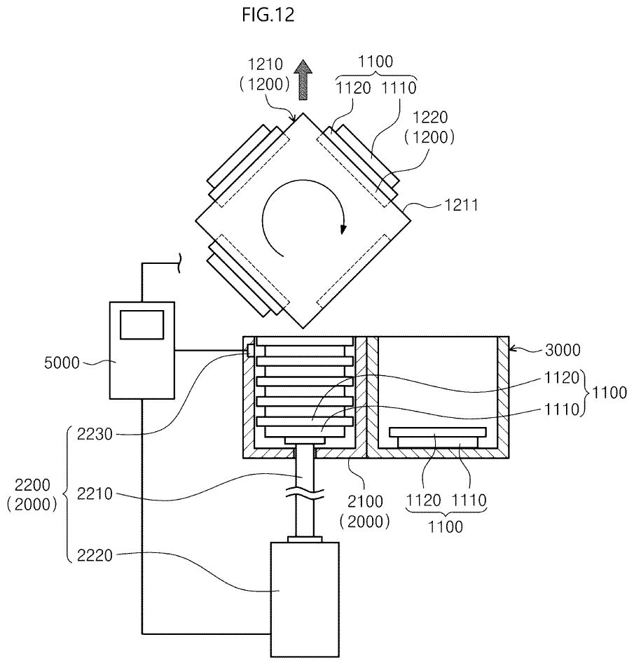

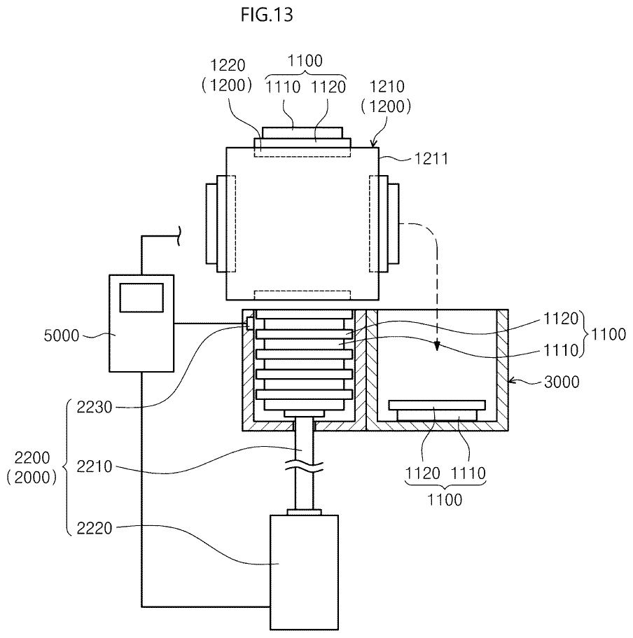

FIG. 9 is a view illustrating a stage body according to at least one example embodiment along a first direction. FIG. 10 is a view illustrating a stage body according to at least one example embodiment along a first direction. FIGS. 11 to 13 are views sequentially illustrating an example of a method for the chip transfer apparatus provided with the stage body of FIG. 9 to replace collets along the first direction.

Referring to FIGS. 9 to 13, the stage body 1210 may be provided as a polygonal column having four or more side faces. For example, the stage body 1210 may be provided as a square column, a regular pentagonal column, or a regular polygonal column having more side faces, etc., but is not limited thereto.

The standby container 2100 and the collection container 3000 are arranged along the second direction 12 and may be positioned in contact with and/or adjacent to each other, but are not limited thereto.

In the case where the stage body 1210 is provided as a polygonal column having four or more side surfaces, when the stage body 1210 is positioned at the attachment position, another detachment surface 1211 adjacent to one of the detachment surfaces 1211 facing the upper surface of the standby container 2100 may be positioned at a position corresponding to a separation position with respect to the collection container 3000, etc. For example, the stage body 1210 may be provided in a size and/or shape such that the another detachment surface 1211 adjacent to one of the detachment surfaces 1211 is positioned above the upper surface of the collection container 3000 when the one of the detachment surfaces 1211 is positioned at a position facing the upper surface of the standby container 2100, etc.

Hereinafter, a method of replacing a collet 1100 on a stage 1200 by a chip transfer apparatus 100 according to some example embodiments of FIG. 9 or FIG. 10 will be described.

Referring to FIG. 11, the stage body 1210 may be positioned at a position above the standby container 2100 where one of the detachment surfaces 1211 faces the upper surface of the standby container 2100, separating a collet 1100 to be separated from the stage body 1210. According to some example embodiments, the stage body 1210 may be positioned at the same position as the attachment position. In this case, another detachment surface 1211 adjacent to one of the detachment surfaces 1211 of the stage body 1210 facing the upper surface of the standby container 2100 may be positioned above the upper surface of the collection container 3000, but is not limited thereto. According to some example embodiments, in this case, another detachable surface 1211 described above may be positioned at a position corresponding to the detached position, but is not limited thereto.

The collet 1100 installed on another detachable surface 1211 described above falls to the collection container 3000 and is collected, when the stage body 1210 is positioned as described above and the electromagnet 1220 installed on another detachable surface 1211 described above is turned off.

Referring to FIG. 12, the stage body 1210 is rotated about the first direction 11 as a rotation axis, to be positioned at the attachment position with respect to the detachable surface 1211 from which a collet 1100 was detached in the process of FIG. 11, but the example embodiments are not limited thereto. In this case, the stage body 1210 may be raised to a height at which the collision is decreased and/or prevented before the rotation, and then lowered to the attachment position again after the rotation, thereby decreasing and/or preventing collision between the stage body 1210 and the standby container 2100 and/or the collet 1100 in the standby during the rotation, but the example embodiments are not limited thereto.

Referring to FIG. 13, when the process of FIG. 12 is completed, the stage body 1210 is positioned at the attachment position, making the detachment surface 1211 from which the collet 1100 was separated in the process of FIG. 11 faces the upper surface of the standby container 2100. In this state, the electromagnet 1220 installed on the detachment surface 1211 facing the upper surface of the standby container 2100 is turned on, causing the collet 1100 to become detached from the standby container 2100 and become attached to the detachment surface 1211 facing the upper surface of the standby container 2100. And, the electromagnet 1220 installed on the detachment surface 1211 located above the collection container 3000 may be turned off, causing the collet 1100 to fall into the collection container 3000 and be collected. That is, in this case, the attachment of the collet 1100 to one detachment surface 1211 and the detachment of the collet 1100 to another detachment surface 1211 may be performed together while the stage body 1210 maintains its position.

In the case of performing the replacement of the collets 1100 for all the detachment surfaces 1211, the processes of FIG. 12 and FIG. 13 may be alternately repeated to perform the replacement of the collets 1100 for all the detachment surfaces 1211 after the process of FIG. 11 is performed, but the example embodiments are not limited thereto. However, the process of separating a collet 1100 in the process of FIG. 13 may not be performed when replacing a collet 1100 for the last order of detachment surface 1211.

In contrast, the processes of FIGS. 11, 12, and 13 that the processes of separating the collet 1100 is omitted may be performed sequentially with respect to each of the target detachment surfaces 1211, making the collet 1100 to be replaced on the stage body 1210, when the replacement of the collet 1100 is performed for one of the detachment surfaces 1211 and/or for detachment surfaces 1211 that are not adjacent to each other, but the example embodiments are not limited thereto.

In the case of the chip transfer apparatus 100 according to some example embodiments of FIGS. 9 and 10, the replacement of the collet 1100 may be performed through the processes of FIGS. 3 and 4, but is not limited thereto.

However, in the case of the chip transfer apparatus 100 according to some example embodiments of FIGS. 1 to 8, when one detachment surface 1211 faces the upper surface of the standby container 2100, the other detachment surfaces 1211 are inclined toward each other and top, the collet 1100 attached to the inclined detachment surface 1211 may not fall into the collection container 3000 even if the electromagnet 1220 is turned off when the method of FIGS. 11 to 13 is applied.

Other features of the chip transfer apparatus 100 to which some example embodiments of FIGS. 5 to 13 are applied may be provided identically or similarly to the features of the chip transfer apparatus 100 of FIGS. 1 to 4.

As described above, the shuttle and the chip transfer apparatus 100 including the same according to some example embodiments of the inventive concepts may automatically replace the collet 1100 by detaching the collet 1100 from the stage body 1210 using the electromagnet 1220. Therefore, the shuttle and the chip transfer apparatus 100 including the same according to some example embodiments of the inventive concepts may shorten the time for replacing the collet 1100. In addition, by providing the stage body 1210 with a polygonal columnar structure, providing the side surface of the stage body 1210 as a detachment surface 1211, and/or providing the stage body 1210 rotatable about the first direction 11, the collet 1100 detached from each detachment surface 1211 may be replaced faster according to and/or based on the order in which the collets 1100 are positioned at the attachment position and the separation position for each detachment surface 1211 while the stage body 1210 rotates.

While some example embodiments of the inventive concepts have been described, it will be apparent to those of ordinary skill in the art that various changes and modifications can be made thereto without departing from the spirit and scope of the inventive concepts as set forth in the following claims.

What is claimed is:

1. A shuttle comprising:
at least one collet configured to support at least one semiconductor chip;
a stage configured to detachably support the at least one collet; and
a rotational driving mechanism configured to rotate the stage in a first direction, the first direction being an axial direction,
the at least one collet including,
a support body configured to support the at least one semiconductor chip, and
a ferromagnetic body on one side of the support body; and
the stage including,
a stage body including at least one detachment surface from which the at least one collet detaches, the detachment surface facing in a direction perpendicular to the first direction, and
at least one electromagnet on the stage body, the at least one electromagnet configured to attach to or detach from the ferromagnetic body.

2. The shuttle of claim 1, wherein the stage body further includes:
a plurality of side surfaces, the plurality of side surfaces arranged in a polygonal columnar shape having a longitudinal direction parallel to the first direction; and
at least one side surface of the plurality of side surfaces is the at least one detachment surface.

3. The shuttle of claim 1, wherein the stage further includes:
a separation auxiliary mechanism configured to apply a force to a collet attached to the detachment surface in a direction away from the detachment surface,
the force being smaller than a magnetic force acting between the ferromagnetic body and the at least one electromagnet in response to the at least one electromagnet being on, and
the force being larger than a residual magnetic force acting between the ferromagnetic body and the at least one electromagnet in response to the at least one electromagnet being off.

4. The shuttle of claim 1, wherein the stage further includes:
at least one guide region including at least one guide slope surface that surrounds an attachment area of the detachment surface, and the at least one guide slope surface is inclined from a top surface of the stage body to the attachment area.

5. The shuttle of claim 4, wherein
an exterior surface of the stage body includes the attachment area and a peripheral area;
the peripheral area is on the exterior surface and the attachment area is recessed into the stage body; and
the guide slope surface is between the attachment area and the peripheral area.

6. The shuttle of claim 4, wherein
the guide region protrudes out of the stage body away from the detachment surface.

7. A chip transfer apparatus, comprising:
a shuttle including at least one collet, the at least one collet configured to support at least one semiconductor chip;
a stage configured to detachably support the at least one collet; and
a rotational driving mechanism configured to rotate the stage in a first direction, the first direction being an axial direction; and
a standby apparatus configured to store the at least one collet prior to the at least one collet being attached to the stage,
the collet including,
a support body configured to support the at least one semiconductor chip, and
a ferromagnetic body installed on one side of the support body; and
the stage including,
a stage body including at least one detachment surface from which the at least one collet detaches, the detachment surface facing a direction perpendicular to the first direction; and
at least one electromagnet on the stage body, the at least one electromagnet configured to attach to and detach from the ferromagnetic body.

8. The chip transfer apparatus of claim 7, wherein
the at least one collet is a plurality of collets;
the standby apparatus is configured to store at least one standby container, the at least one standby container including a cavity and an open upper surface, the cavity configured to store the plurality of collets in a stacked manner; and
the electromagnet is configured to be turned on in response to the stage body being positioned at an attachment position, and
the attachment position being a position at which the stage body is positioned above the standby container and the detachment surface faces the upper surface of the standby container.

9. The chip transfer apparatus of claim 8, further comprising:
the standby apparatus is configured to store a plurality of collection containers;
each of the plurality of collection container includes a cavity and an open surface, the cavity configured to receive the at least one collet that are detached from the detachment surface;
the electromagnet is configured to be turned off in response to the stage body being positioned at a separation position; and
the separation position is a position in which the stage body is positioned above the collection container and the collet that detaches from the detachment surface falls to the upper surface of the collection container.

10. The chip transfer apparatus of claim 9, wherein the stage body further includes:
a plurality of side surfaces, the plurality of side surfaces arranged in a polygonal columnar shape having a longitudinal direction parallel to the first direction; and
at least one side surface of the side surfaces is the at least one detachment surface.

11. The chip transfer apparatus of claim 10, wherein
the stage body includes four or more side surfaces;
the at least one standby container and collection container are arranged along a second direction perpendicular to the first direction;
the at least one detachment surface is a plurality of detachment surfaces;
a first detachment surface of the plurality of detachment surfaces faces the upper surface of the at least one standby container; and
a second detachment surface of the plurality of detachment surfaces is adjacent to the first detachment surface and is positioned at a position corresponding to the separation position with respect to the collection container in response to the stage body being positioned at the attachment position.

12. The chip transfer apparatus of claim 7, wherein the standby apparatus further includes:
a collet lifting device configured to raise a collet remaining in the at least one standby container as high as a height of the collet in response to a highest one of the collets stored in the at least one standby container being removed from the at least one standby container.

13. The chip transfer apparatus of claim 7, wherein the stage further includes:
a separation auxiliary mechanism configured to apply a force to a collet attached to the detachment surface in a direction away from the detachment surface,
the force being smaller than a magnetic force acting between the ferromagnetic body and the at least one electromagnet in response to the at least one electromagnet being on, and
the force being larger than a residual magnetic force acting between the ferromagnetic body and the at least one electromagnet in response to the electromagnet being off.

14. The chip transfer apparatus of claim 7, wherein the stage further includes:
a guide region including at least one guide slope surface that surrounds an attachment area of the detachment surface, and
the at least one guide slope surface is inclined toward an interior of the stage body and the attachment area.

15. A chip transfer apparatus, comprising:
a shuttle configured to store at least one collet, the collet configured to support at least one semiconductor chip;
a stage configured to detachably support the at least one collet;
a rotational driving mechanism configured to rotate the stage in a first direction, the first direction being an axial direction; and
a collection container configured to collect the at least one collet removed from the stage,
the collet including,
a support body configured to support the at least one semiconductor chip, and
a ferromagnetic body on one side of the support body;
the stage including,
a stage body including at least one detachment surface from which the at least one collet detaches, the detachment surface facing in a direction perpendicular to the first direction; and
at least one electromagnet on the stage body, the at least one electromagnet configured to attach to or detach from the ferromagnetic body.

16. The chip transfer apparatus of claim 15, wherein
the collection container includes an open upper surface and a cavity, the cavity configured to receive a collet that is removed from the detachment surface;
the electromagnet is configured to be turned off in response to the stage body being positioned at a separation position; and
the separation position is a position at which the stage body is positioned above the collection container and the detachment surface faces the upper surface of the collection container.

17. The chip transfer apparatus of claim 15, wherein the stage body further includes:
a plurality of side surfaces, the plurality of side surfaces arranged in a polygonal columnar shape having a longitudinal direction parallel to the first direction; and
at least one side surface of the plurality of side surfaces is the at least one detachment surface.

18. The chip transfer apparatus of claim 17, wherein
the stage body includes four or more side surfaces;
the collection container includes an open upper surface and a cavity configured to receive a collet that is removed from the detachment surface;
the electromagnet is configured to be turned off in response to the stage body being positioned at a separation position; and
the separation position is a position in which the stage body is positioned above the collection container and the collet that is removed from the detachment surface falls to the upper surface of the collection container.

19. The chip transfer apparatus of claim 15, wherein the stage further includes:
a separation auxiliary mechanism configured to apply a force to a collet attached to the detachment surface in a direction away from the detachment surface;
the force being smaller than a magnetic force acting between the ferromagnetic body and the electromagnet in response to the electromagnet being on; and
the force being larger than a residual magnetic force acting between the ferromagnetic body and the electromagnet in response to the electromagnet being off.

20. The chip transfer apparatus of claim 15, wherein the stage further includes:
a guide region including at least one guide slope surface that surrounds an attachment area of the detachment surface, and the at least one guide slope surface is inclined toward an interior of the stage body and the attachment area.
